(19) United States
(12) Patent Application Publication
(10) Pub. No.: US 2006/0019176 A1
(43) Pub. Date: Jan. 26, 2006

(54) Chromeless phase shift mask and method of fabricating the same

(76) Inventors: Sung-hyuck Kim, Suwon-si (KR); In-kyun Shin, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/067,338

(22) Filed: Feb. 28, 2005

(30) Foreign Application Priority Data
Jul. 23, 2004 (KR) 2004-57546

(51) Int. Cl. G03C 5/00; G03F 1/00

(52) U.S. Cl. 430/5; 430/322; 430/323; 430/324

(57) ABSTRACT

A chromeless phase shift mask (PSM) can be used in a single exposure process to produce a pattern whose features have different after development inspection critical dimensions (ADI CDs). The chromeless PSM includes a mask and a plurality of phase shifters constituted by recesses in the mask substrate. The recesses have different depths so that the phase shifters will produce different phase differences in the exposure light transmitted by the mask. The recesses are formed by etching the mask substrate. The mask substrate is initially etched to form a first set of the recesses. Some of these recesses are left as is to constitute the first phase shifters. The substrate is then further etched at the location of at least another of the first recesses to form the second phase shifter(s).

### BACKGROUND OF THE INVENTION

1. Field of the Invention

The present invention relates to a phase shift mask and to a method of fabricating the same. More particularly, the present invention relates to a chromeless phase shift mask and to a method of fabricating the same.

2. Description of the Related Art

Reductions in the design rule of semiconductor devices are accompanied by decreases in the margin of the processes used to fabricate the devices, especially with respect to photolithography. That is, limitations inherent in photolithography make it difficult to form small patterns, i.e., micro patterns, on a wafer. In light of this, using an ArF or F₂ light source instead of a conventional KrF light source has been studied as a way to secure a large margin in a photolithographic process. However, the use of an ArF light source for mass production is problematic. Accordingly, resolution enhancement technology (RET) has also been researched as a way to enhance conventional photolithography processes. RET aims to develop a means by which a micro pattern can be formed using a conventional light source, e.g., a KrF light source.

One approach of RET is to use a phase shift mask (PSM), in place of a conventional a binary mask (BM), to increase the resolution of the photolithography process. The BM merely consists of a transparent substrate and an opaque chrome pattern disposed on the substrate. On the other hand, known types of PSMs include a rim-shifting PSM, an attenuated PSM (attPSM), an alternating PSM (ALT-PSM), a half-tone PSM, and a chromeless PSM. A rim-shifting PSM is made by forming a patterned layer of material, for inducing a phase shift, on an opaque chrome pattern disposed on a transparent substrate. An attenuated PSM (attPSM) is made by adding an Mo layer to an existing BM. A half-tone PSM is made by forming a half-tone film on a substrate to induce a phase difference in the light transmitted by the PSM. An alternating PSM (ALT-PSM) is made by forming a layer of material on a transparent quartz substrate, and patterning the material to form phase shifters alternately disposed with exposed areas of the transparent substrate. A chromeless PSM is made by forming recesses, in a transparent quartz substrate, the recesses inducing a phase shift in the light transmitted by the PSM and being alternately disposed with exposed areas of the transparent substrate.

Among these PSMs, attPSMs are the most widely used for the mass production of highly integrated semiconductor devices. However, attPSMs use a film having a transmittance of 5-20%, which causes problems whose existence is confirmed by the presence of side lobes in a graph of the intensity of the image transmitted by the mask. An opaque pattern added to the mask can rid the mask of these problems. However, adding such an opaque pattern increases the turn around time (TAT) for the fabrication of the mask and hence, decreases the yield of the fabrication process. In addition, the Mo layer of an attPSM creates a haze. More specifically, a haze abruptly occurs on the front side of an attPSM after a certain number of photolithographic processes are performed using the attPSM, whereupon the yield is reduced to 0%. Accordingly, the attPSM needs to be cleaned periodically to remove the haze from the front surface thereof. Nonetheless, the haze cannot be completely prevented from creating significant problems even if the attPSM is periodically cleaned.

Accordingly, the chromeless PSM has gained consideration for use in forming a micro pattern on a wafer. As mentioned above, the phase shifter of a chromeless PSM is formed by etching a mask substrate to a predetermined depth. In other words, the phase shifters of a chromeless PSM are constituted by a pattern of recesses in the mask substrate. However, it is difficult to use a chromeless PSM in fabricating semiconductor devices because of the following fundamental limitations of the chromeless PSM.

FIG. 1 is a graph of a characteristic of conventional chromeless PSMs showing design critical dimensions (CD) versus after development inspection CDs (ADI CD). As shown in FIG. 1, there is a region A wherein the ADI CD does not increase even as the design CD of the conventional chromeless PSM becomes larger. The region where the ADI CD decreases beyond region A is referred to as the CD dead zone. Thus, as also shown in the graph, a conventional chromeless PSM having a design CD of 70 nm and inducing a phase difference of 180 degrees can produce a pattern having an ADI CD of up to 80 nm. However, a chromeless PSM having a design CD greater than 70 nm is basically useless because it can not produce a pattern having an ADI CD of greater than 80 nm.

For this reason, a photo mask as illustrated in FIG. 2 is conventionally used to form a pattern having ADI CDs of both 80 nm and 90 nm. Referring to FIG. 2, the photomask includes a chromeless PSM section 20 for producing a pattern having an ADI CD of 80 nm, and a BM section 30 for producing a pattern having an ADI CD of 90 nm. The PSM section 20 is made by etching a recess 15 in the mask substrate 10. The BM section 30 is made by forming a chrome pattern 25 on the mask substrate 10.

However, a BM provides a smaller process margin than a chromeless PSM. Accordingly, the margin of a photolithographic process employing the integrated photo mask illustrated in FIG. 2 is limited by the BM section 30

### SUMMARY OF THE INVENTION

An object of the present invention is to provides a chromeless phase shift mask (PSM) that does not have a critical dimension (CD) dead zone.

Another object of the present invention is to provide a chromeless phase shift mask (PSM) that can be used in a single exposure process to produce a pattern whose features have different after development inspection CDs (ADI CDs), respectively.

Still, another object of the present invention is to provide a chromeless phase shift mask (PSM) that can be used in a single exposure process to produce a pattern whose features have different after development inspection CDs (ADI CDs), including an ADI CD of greater than 80 nm.

Likewise, objects of the present invention include providing a method of fabricating a chromeless PSM having the advantages noted above.

According to an aspect of the present invention, there is provided a chromeless phase shift mask including a mask substrate and a plurality of phase shifters constituted, respectively, by recesses of different depths in the mask substrate.

According to another aspect of the present invention, there is provided a method of fabricating a chromeless phase shift mask that includes etching a mask substrate to different depths to form a plurality of phase shifters that will produce various phase differences in the exposure light transmitted by the mask during a photolithographic (exposure) process.

According to still another aspect of the present invention, there is provided a method of fabricating a chromeless phase shift mask which includes initial and subsequent etching processes to form phase shifters that will produce different phase differences in the exposure light transmitted by the mask during a photolithographic (exposure) process. In the method, a first resist pattern is formed on the entire surface of a mask substrate. The mask substrate is then initially etched using the first resist pattern as an etch mask to form first recesses in the substrate. Then the first resist pattern is removed. Next, a second resist pattern is formed to expose at least one of the first recesses while, in turn, covering one or more of the first recesses. The mask substrate is then further etched using the second resist pattern as an etch mask to extend the exposed recesses further into the mask substrate. The second resist pattern is then removed. Those recesses which were covered by the second resist pattern constitute the first phase shifters, whereas those recesses that were extended deeper into the substrate constitute the second phase shifters.

According to yet another aspect of the present invention, there is provided a method of fabricating a chromeless phase shift mask wherein simulations are used to predetermine the depths to which the mask substrate should be etched. In this method, ADI CDs of features of a pattern which will be produced in a photolithographic process by a chromeless phase shift mask are determined under a simulation wherein the phase shifters of the chromeless phase shift mask have various design CDs. The other parameters of the simulation are established so that the phase shifters will produce a phase difference of 150 degrees. The simulations also correlates the ADI CDs to the design CDs. Next, an optimum design CD is selected using the correlation of the ADI CDs to the design CDs. The optimum design CD is that which is determined to produce an optimal contrast in the image transmitted by the chromeless phase mask during the photolithographic process. Also, the optimal dose of the exposure light is determined. This dose is that which will produce a minimum target ADI CD when a chromeless phase shift mask whose phase shifters have the optimum design CD is used in the photolithographic process.

Next, another set of ADI CDs of features of a pattern which will be produced by the photolithographic process when the process uses a chromeless phase shift mask are determined under a simulation wherein the phase shifters of the chromeless phase shift mask each have the optimum design CD and produce several different phase differences in a range 150 to 180 degrees, and the process is carried out using the exposure light at the optimal dose. This simulation also correlates the set of ADI CDs to the phase differences in the range of 150 to 180 degrees. Next, this correlation is used to determine first and second phase differences, in the range of 150 to 180 degrees, which when produced in the exposure light during a photolithographic process will produce a pattern whose features have first and second desired ADI CDs, respectively.

Then, an actual mask substrate is etched to form first recesses each having a width equal to the optimal design CD and a depth that will produce the first phase difference. Finally, the mask substrate is further etched to extend (at least) one of the first recesses further into the mask to a depth that will produce the second phase difference.

### BRIEF DESCRIPTION OF THE DRAWINGS

The above and other objects, features and advantages of the present invention will become more apparent from the following detailed description of the preferred embodiments thereof made with reference to the attached drawings in which:

FIG. 1 is a graph of design critical dimensions (CD) versus after development inspection CDs (ADI CD) characteristic of chromeless phase shift masks (PSM);

FIG. 2 is a sectional view of a conventional photo mask for use in forming a pattern having both an 80 nm ADI CD and a 90 nm ADI CD;

FIG. 3 is a sectional view of a chromeless PSM according to the present invention;

FIGS. 4 through 11 are sectional views of a mask substrate illustrating stages in a method of fabricating the chromeless PSM shown in FIG. 3;

FIG. 12 is a flowchart of a method of fabricating a chromeless PSM according to the present invention;

FIG. 13 is graph of the result of simulations used to predetermine ADI CDs as the result of photolithography processes using chromeless PSMs fabricated according to the present invention, wherein the phase shifters of the PSMs were provided with a range of design CDs and produced phase differences between 150 and 180 degrees;

FIG. 14 is a graph of the results of a simulation of a photolithography process using a chromeless PSM designed according to the present invention to produce a phase difference of 165 degrees, and illustrates a margin of the process; and

FIG. 15 is a graph of the results of a simulation of a photolithography process using a chromeless PSM designed according to the present invention to produce a phase difference of 180 degrees, and illustrates a margin of the process.

### DETAILED DESCRIPTION OF THE PREFERRED EMBODIMENTS

The present invention will now be described more fully with reference to the accompanying drawings. However, before the description proceeds, it should be noted that a chromeless phase shift mask (PSM) according to the present invention can be used to fabricate various micro electronic devices. For example, the chromeless PSM may be used to fabricate highly integrated semiconductor memory devices such as dynamic random access memory (DRAM) devices, static random access memory (SRAM) devices, and flash memory devices; processors such as central processing units (CPUs), digital signal processors (DSPs), and combinations of CPUs and DSPs; application specific integrated circuits (ASICs); micro-electro-mechanical (MEM) devices; optoelectronic devices; and display devices. Also, like reference numerals denote like elements throughout the drawings.

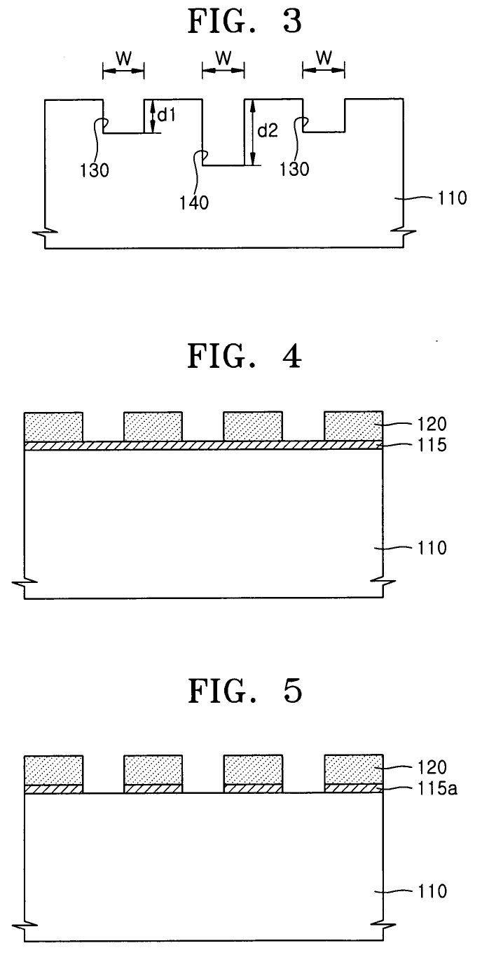

Referring first to FIG. 3, the chromeless PSM includes a mask substrate 110 and a plurality of phase shifters 130 and 140 formed by etching the mask substrate 110. The mask substrate 110 is transparent to light emitted by a light source of a photolithographic exposure device (for example, an i-line laser, a KrF excimer laser, or an ArF excimer laser). The material of the mask substrate 110 may be glass, fused silica, or quartz. The plurality of phase shifters 130 and 140 have the same width “w” but have different depths d1 and d2. Preferably, the phase shifter 140 having the greatest depth produces a phase difference of less than 180 degrees.

Generally, when the mask substrate 110 has a refractive index nᵢ and the exposure light has a wavelength λ, the relationship between the phase difference ΔΦ produced by the recess type of phase shifter and the depth “t” of the recess is defined by Equation (1).
ΔΦ=2π(nᵢ−1)t/λ (1)

For example, in a case in which the material of the mask substrate 110 is fused silica, a phase difference of 180 degrees is produced when the depth (t) of the recess is 2470 Å and a KrF excimer laser having a wavelength (λ) of 248 nm is used. Similarly, a phase difference of 180 degrees is produced when the depth (t) of the recess is 1850 Å and an ArF excimer laser having a wavelength (λ) of 193 nm is used. Also, when the material of the mask substrate 110 is quartz, the phase difference increases by about 1 degree for every increase of 13.4 Å in the depth of the recess. As shown in Equation (1), for a given wavelength λ, the phase difference ΔΦ increases as the depth “t” increases. Accordingly, as the depth “t” increases, the intensity of the transmitted light decreases.

Therefore, the phase shifter 140 having the greater depth d2 produces a greater. phase difference than the other phase shifters 130. Accordingly, although the phase shifters 130 and 140 have the same width “w”, the pattern produced by the mask will comprise features having different ADI CDs due to the different phase differences produced by the phase shifters' 130 and 140 having different etch depths d1 and d2, respectively. The phase shifter 140 having the greater etch depth d2 produces a feature of the pattern having a greater ADI CD than those features produced by the other phase shifters 130.

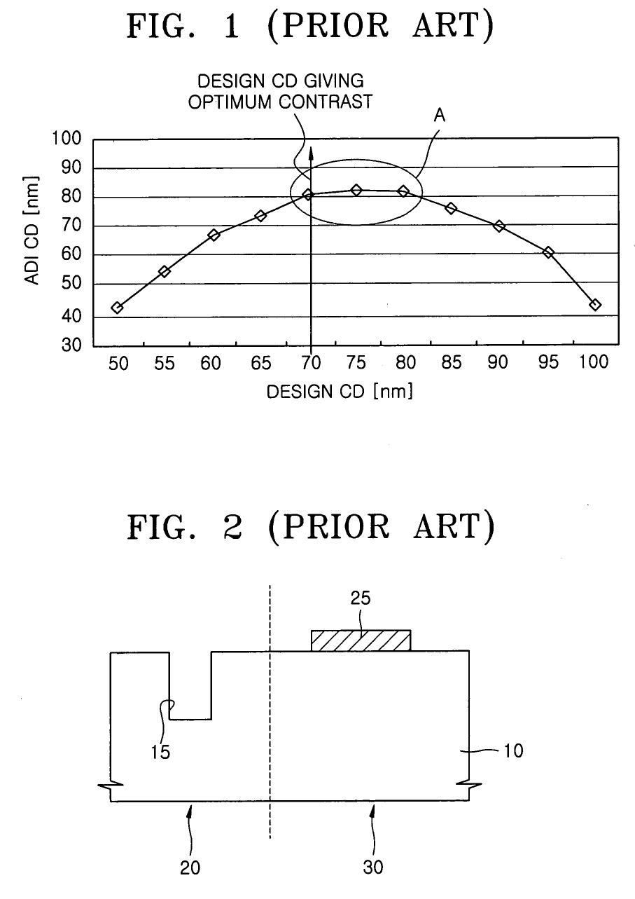

Accordingly, a chromeless PSM according to the present invention can produce a pattern whose features have, respectively, a first ADI CD of 80 nm or less, and a second ADI CD greater than 80 nm. Such a result can be achieved using a conventional light source by appropriately designing the mask in terms of the widths of the phase shifters 130 and 140, the distance (i.e., pitch) between the phase shifters 130 and 140, and the depths d1 and d2 of the phase shifters 130 and 140. On the other hand, a conventional chromeless PSM cannot be used to produce a pattern having an ADI CD of greater than 80 nm (i.e., an ADI CD within a CD dead zone) for the reasons described earlier in connection with FIG. 1.

FIGS. 4 through 11 illustrate a method of fabricating a chromeless PSM according to the present invention. Referring to FIG. 4, a chrome layer 115 is formed on the mask substrate 110. The chrome layer 115 may be formed by sputtering. A resist is spread on the chrome layer 115 and then patterned, thereby forming a first resist pattern 120. The chrome layer 115 enhances the adherence of the first resist pattern 120 to the mask substrate 110 and functions as an etch mask together with the first resist pattern 120 when the mask substrate 110 is etched.

More specifically, an e-beam is scanned the surface of the resist to expose a select portion of the resist. At this time, the chrome layer 115 also functions as a charge preventing layer to prevent charges from the e-beam from accumulating on the substrate. As an alternative to the chrome layer 115, the mask substrate 110 may be surface-treated with hexamethyldisilazane (HMDS) to enhance the adherence of the first resist pattern 120 to the mask substrate 110. In this case, a laser exposure system may be used to expose the resist.

Next, a development system sprays the exposed resist with developer, and the developer is spread across the resist using a spin-coating or is allowed to puddle. As a result, a portion of the resist is removed, e.g., the exposed portion. Note, though, that the physical characteristics of the chemical bond of the resist are changed when a laser beam or an e-beam is scanned across the surface of the resist. In this respect, the chrome layer 115 or the HMDS treatment prevents the first resist pattern 120 from peeling from the mask substrate 110 during the developing process. Finally, in the case of the e-beam process, the resist pattern 120 is fired (hard baked) and remnants of the resist are removed using plasma (de-scumming).

Referring to FIG. 5, the chrome layer 115 is etched using the first resist pattern 120 as an etch mask, thereby forming a chrome layer pattern 115a. In this case, wet etching may be used.

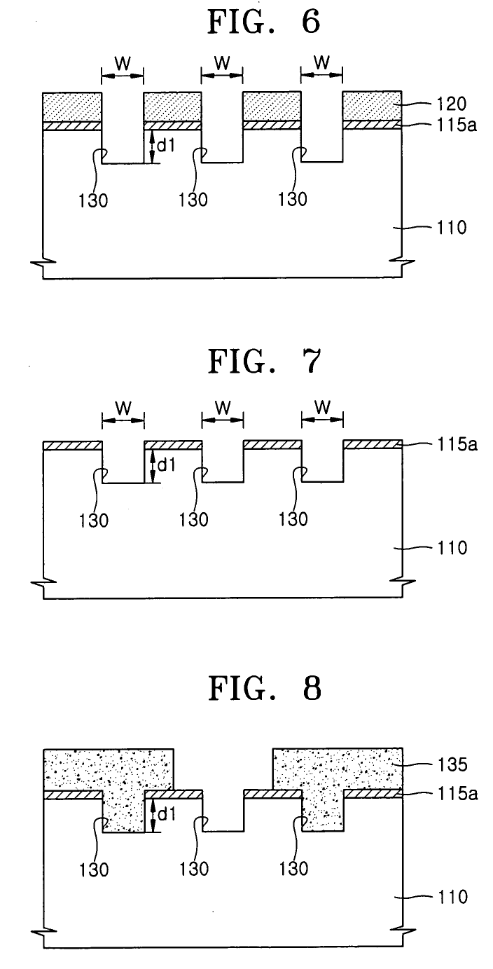

Next, as shown in FIG. 6, the mask substrate 110 is etched using the first resist pattern 120 as an etch mask, thereby forming a plurality of phase shifters 130 having a first depth d1. The plurality of the phase shifters 130 have the same width “W”. In the case in which the chrome layer 115 is formed on the mask substrate 110, the chrome layer pattern 115a also serves as an etch mask.

Preferably, the mask substrate 110 is wet and dry etched to form the phase shifters 130 so that the size (i.e., the width and depth) of the phase shifters 130 can be precisely controlled. Specifically, a duty ratio of precisely 1:1 can be attained using a combination of wet and dry etching processes. Alternatively, the phase shifters 130 may be formed by dry reactive ion etching using CF₄+O₂ gas.

The mask substrate 110 may be etched in a plurality of stages to form the phase shifters 130. In this case, the amount of etching that occurs during each stage may be calculated and used in conducting the subsequent stage to ensure precision in attaining the final depth of the phase shifters 130. That is, phase shifters 130 that will produce the desired phase difference can be formed in this way.

Next, the first resist pattern 120 is removed from the mask substrate 110 as shown in FIG. 7. Subsequently, the structure is cleaned.

Next, referring to FIG. 8, a second resist pattern 135 is formed to expose at least one of the phase shifters 130. At this time, the entire surface of the mask substrate 110 may be treated with HMDS to enhance the adherence of the second resist pattern 135 to the mask substrate 110.

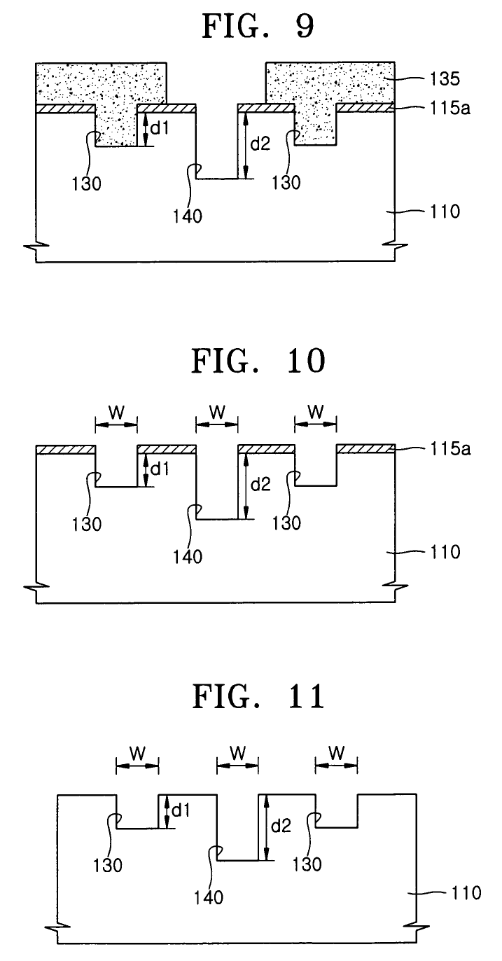

Referring to FIG. 9, the mask substrate 110 is etched at each phase shifter 130 exposed by the second resist pattern 135, thereby forming a phase shifter 140 having the second depth d2. The etching may be controlled so that the phase shifter 140 produces a phase difference of less than 180 degrees. In this process, the mask substrate 110 can not be etched too deeply or else it becomes difficult to maintain control over the etching process and thereby obtain an accurate etch depth. That is, if the phase shifter 140 is designed to be too deep, there is a good chance that the etching process will be inaccurate, and that the resulting phase shifter 140 will produce a phase difference different from the desired phase difference.

In any case, the mask substrate 110 is preferably dry and wet etched to form the phase shifter 140. Alternatively, dry reactive ion etching using CF₄+O₂ gas may be used to form the phase shifter 140. Also, the etching process is preferably performed in a plurality of stages, wherein the amount of etching at each stage is calculated and used to conduct a subsequent stage such that excellent uniformity is achieved. Finally, the second resist pattern 135 and the chrome layer pattern 115a are removed, as shown in FIGS. 10 and 11. Then, the mask is cleaned.

In addition, the mask substrate 110 may be further etched one or more times at one or some of the phase shifters 130 and 140 to change the depth d1 and/or d2 without changing the width W. In other words, a resist pattern exposing one or more of the phase shifters 130 and 140 can be again formed on the mask substrate 110, and the mask substrate 110 can be etched at each phase shifter exposed through the resist pattern. As a result, two or more phase shifters having depths greater than the depth of the other phase shifters can be formed. Therefore, a chromeless PSM according to the present invention can be used to form a pattern whose features have more than two ADI CDs.

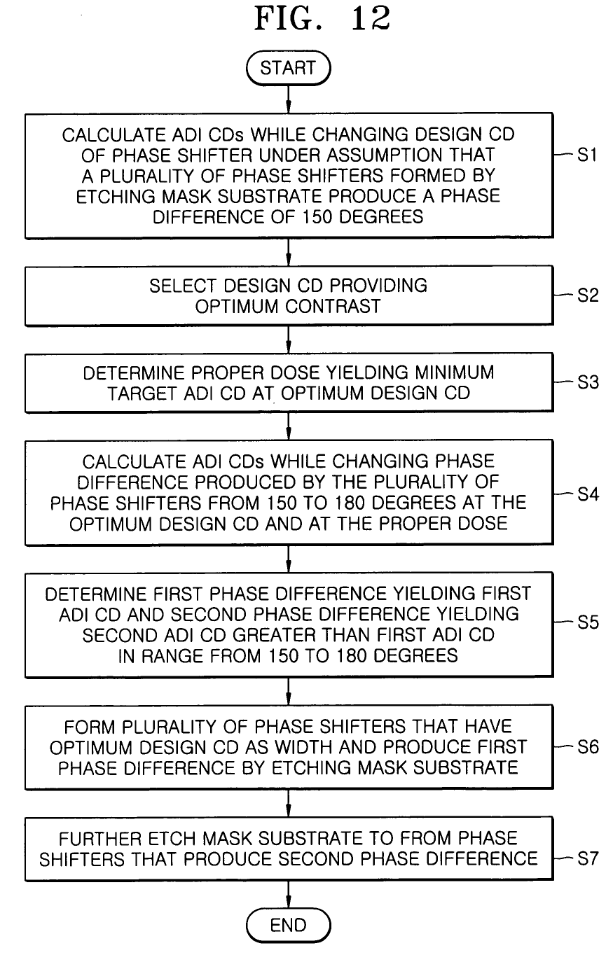

FIG. 12 is a flowchart of a method of fabricating a chromeless PSM according to the present invention. In the method, the calculation, selection, and detection steps may be performed using a SOLID-C simulation program, i.e., software that is widely used per se in the field.

Referring to FIG. 12, in operation S1, ADI CDs of features of a pattern produced by a chromeless phase shift mask are calculated, under conditions wherein a design CD of the phase shifters of the mask is varied and other parameters are fixed so that the phase shifters will produce a phase difference of 150 degrees. The ADI CDs are correlated with the associated design CDs.

Next, in operation S2, the design CD yielding an optimum contrast is selected. To this end, a contrast curve in which the design CDs are plotted is produced. The design CD by which an optimum focus can be obtained is selected from the contrast curve as the optimum design CD. For example, in a simulation in which the exposure system had a numerical aperture (NA) of 0.75 and an aperture diameter of σ, and a region from 0.35σ to 0.65σ was used as a light transmitting region, the optimum design CD selected was about 70 nm.

Subsequently, in operation S3, the dose yielding a minimum target ADI CD at the optimum design CD is selected.

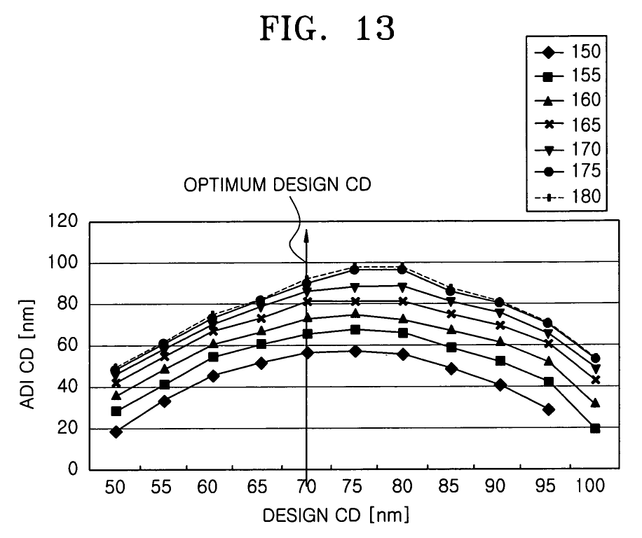

In operation S4, ADI CDs of features produced using the selected dose for a chromeless phase shift mask whose phase shifters have the optimum design CD, but are designed to produce a phase difference of 180 degrees instead of 150 degrees, are calculated. For example, simulations were carried out in which the phase difference was increased from 150 degrees in increments of 5 degrees. The results of these simulations were used to generate the graph of FIG. 13, i.e., the correlation between the design CDs and the ADI CDs.

That is, FIG. 13 is graph of the result of simulations of photolithography processes using chromeless PSMs fabricated according to the present invention, wherein the phase shifters of the PSMs were provided with a range of design CDs and produced phase differences between 150 and 180 degrees. The design CDs were plotted versus the ADI CDs of the features of the pattern that would be obtained. Referring to FIG. 13, as the phase difference increases, the design CD-ADI CD curve shifts upward. When the phase shifter has the optimum CD of 70 nm and produces a phase difference of 150 degrees, the ADI CD is less than 70 nm, but when the phase shifter has the optimum CD of 70 nm and produces a phase difference of 180 degrees, the ADI CD is about 90 nm. Thus, the results of the simulation confirm that the present invention can be used to produce a pattern having an ADI CD within what was considered to be a CD dead zone of a conventional chromeless PSM.

Next, in operation S5, a first phase difference that will produce a pattern having a desired first ADI CD and a second phase difference that will produce a pattern having a second desired ADI CD, greater than the first ADI CD, are discerned for phase shifters having the optimum design CD. For example, these phase differences are taken from the curves in FIG. 13 intersected by the points where the vertical line representing the value of the optimum design CD crosses the horizontal lines representing the values of the desired ADI CDs. Thus, if the first and second desired ADI CDs are 80 nm and 90 nm, respectively, the first and second phase differences are discerned as 165 degrees and 180 degrees, respectively.

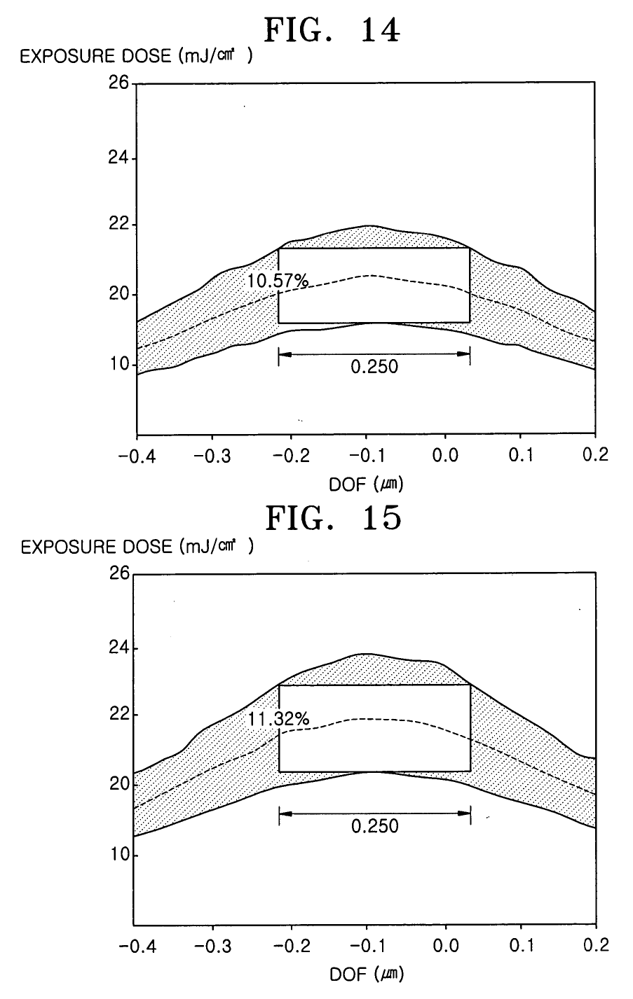

Meanwhile, simulations were carried out to check whether the process margins were comparable for a process carried out using a PSM having the phase shifters designed to produce a phase difference of 165 degrees and a PSM having the phase shifters designed to produce a phase difference of 180 degrees. FIG. 14 is a graph illustrating the former process margin (for the phase difference of 165 degrees), and FIG. 15 is a graph illustrating the latter process margin (for the phase difference of 180 degrees).

Referring to FIG. 14, an exposure latitude (EL) of about 10.57% was secured over a depth of focus (DOF) of about 0.250 μm for the process employing the PSM that produced a phase difference of 165 degrees. Referring to FIG. 15, an EL of about 11.32% was secured over a DOF of about 0.250 μm for the process employing the PSM that produced a phase difference of 180 degrees. The graphs of FIGS. 14 and 15 show that almost no difference exists in the process margins as long as an appropriate dose is used. Accordingly, the graphs show that the chromeless PSM according to the present invention can be put into practice effectively, i.e., can be used in a single exposure process to form a pattern whose features have different ADI CDs.

Next, in operation S6, a plurality of phase shifters that have the optimum design CD as a width and which produce the first phase difference are formed by etching the mask substrate. In operation S7, the mask substrate is further etched at one or more of the phase shifters to fabricate a second phase shifter(s) that will produce the second phase difference. Operations S6 and S7 may be performed according to the method described with reference to FIGS. 4 through 11.

More specifically, the steps described with reference to FIGS. 4 through 7 are performed to form the phase shifters 130. Here, the width “W” of the phase shifters 130 is set to the optimum design CD, for example, 70 nm, and the depth d1 of the phase shifters 130 is set to a value of, for example, 165 degrees, such that the phase shifters 130 will produce the first phase difference. Next, the steps described with reference to FIGS. 8 through 11 are performed, i.e., the mask substrate is further etched at the location of a phase shifter 130 to thereby form the phase shifter 140 having the depth d2. The depth d2 is such that the phase shifter will produce the second phase difference of, for example, 180 degrees. When a chromeless PSM fabricated using the above-described method is used to produce a pattern, the pattern will comprise features having ADI CDs of 80 nm and 90 nm, respectively. Accordingly, the present invention can produce a pattern having an ADI CD of greater than 80 nm, i.e. one that is within the CD dead zone of a conventional chromeless PSM.

As described above, according to the present invention, the phase shifters of the chromeless PSM have different depths designed to control the phase differences and thereby avoid the creation of a CD dead zone as a characteristic of the mask. In other words, the mask may have phase shifters whose design CD is greater than 80 nm, i.e., a value within the CD dead zone of a conventional chromeless PSM. This is made possible by using an exposure dose that secures a process margin comparable to that which is secured when the mask only produces a phase difference of 180 degrees. Accordingly, a pattern having various ADI CDs can be produced using only a single chromeless PSM according to the present invention.

Also, in a method of fabricating a chromeless PSM according to the present invention, the mask substrate is etched to form the phase shifters that will produce a first phase difference, and then the mask is additionally etched at only some (one or more) of those recesses. Such method is relatively simple.

Still further, the basic steps of forming a resist pattern exposing only one or some of the existing recesses and of further etching the substrate at the exposed recess or recesses may be repeated to form several phase shifters having different depths. Accordingly, the present invention can fabricate a chromeless PSM capable of producing a pattern whose features have more than two different ADI CDs.

Finally, although the present invention has been particularly shown and described with reference to the preferred embodiments thereof, it will be understood by those of ordinary skill in the art that various changes in form and details may be made thereto without departing from the spirit and scope of the present invention as defined by the following claims.

What is claimed is:

1. A chromeless phase shift mask comprising:
a mask substrate; and
a plurality of phase shifters which produce a phase difference in exposure light, of a given wavelength, transmitted by the mask, wherein the phase shifters are constituted by recesses in the mask substrate, and respective ones of the phase shifters have different depths.

2. The chromeless phase shift mask of claim 1, wherein the plurality of phase shifters have the same width.

3. The chromeless phase shift mask of claim 1, wherein the phase shifter having the greatest depth produces a phase difference of 180 degrees or less for the exposure light.

4. A method of fabricating a chromeless phase shift mask, comprising:
etching a mask substrate to form a plurality of first recesses therein, at least one of the first recesses constituting a first phase shifter which produces a first phase difference in exposure light, of a given wavelength, transmitted by the mask; and
subsequently further etching the mask substrate only at the location of another one of the first recesses to extend the another one of the other first recesses further into the substrate and thereby form a second recess constituting a second phase shifter, whereby the second phase shifter will produce a phase difference, different from that of the first phase difference produced by each said first phase shifter, in the exposure light transmitted by the mask.

5. The method of claim 4, further comprising further etching the mask substrate at the location of the first and/or second recesses to a depth different from that of the first and second recesses, respectively, to thereby form at least one other phase shifter which will produce a phase difference, different from the first and second phase differences, in the exposure light transmitted by the mask.

6. The method of claim 4, wherein the further etching of the mask substrate comprises forming a second phase shifter that will produce a phase difference of 180 degrees or less in the exposure light transmitted by the mask.

7. The method of claim 4, wherein the forming of the first and second phase shifters comprises forming the first and second phase shifters to have the same width.

8. A method of fabricating a chromeless phase shift mask, comprising:
forming a first resist pattern over an entire surface of a mask substrate;
etching the mask substrate using the first resist pattern as an etch mask to forming a plurality of first recesses having a first depth in the substrate, at least one of the first recesses each constituting a first phase shifter;
removing the first resist pattern;
forming a second resist pattern that exposes one of the first recesses and covers the at least one of the first recesses;
further etching the mask substrate at the first recess exposed by the second resist pattern to thereby form a recess having a second depth greater than the first depth, whereby the recess having the second depth constitutes a second phase shifter; and
removing the second resist pattern.

9. The method of claim 8, further comprising treating the entire surface of the mask substrate with hexamethyldisilazane (HMDS) before the first resist pattern is formed, and again treating the entire surface of the mask substrate with hexamethyldisilazane (HMDS) before the second resist pattern is formed.

10. The method of claim 8, further comprising:
forming a chrome layer over the entire surface of the mask substrate before the first resist pattern is formed;
etching the chrome layer using the first resist pattern as an etch mask to form a chrome layer pattern; and
removing the chrome layer pattern after the mask substrate is further etched at the at least one first recess,
wherein the etching of the mask substrate to form the first recesses comprises using the chrome layer pattern and the first resist pattern as etch masks.

11. The method of claim 8, wherein the etching of the mask substrate to form the recesses having the first depth and the etching of the mask substrate to form the recess having the second depth both comprise dry and wet etching processes.

12. The method of claim 8, wherein the etching of the mask substrate to form the recesses having the first depth and the etching of the mask substrate to form the recess having the second depth both comprise dry reactive ion etching using CF₄+O₂ gas.

13. The method of claim 8, wherein the etching of the mask substrate to form the recesses having the first depth and the etching of the mask substrate to form the recess having the second depth are each performed in a plurality of stages, and comprise calculating the amount of etching that occurs during each of the stages and using the calculated amount in conducting the subsequent stage.

14. The method of claim 8, wherein the etching of the mask substrate to form the recess having the second depth is controlled such that the second phase shifter will produce a phase difference of 180 degrees or less in exposure light. Of a given wavelength, transmitted by the mask.

15. The method of claim 8, wherein the etching of the mask substrate to form the recesses having the first depth comprises forming the recesses to have the same width.

16. A method of fabricating a chromeless phase shift mask, comprising:
determining ADI CDs (after design inspection critical dimensions) of features of a pattern which will be produced in a photolithographic process by a chromeless phase shift mask, under conditions wherein the phase shifters of the chromeless phase shift mask have various design CDs (critical dimensions) and other parameters are established so that the phase shifters will produce a phase difference of 150 degrees in the exposure light transmitted by the mask during the photolithographic process;
correlating the ADI CDs to the design CDs;
using the correlation of the ADI CDs to the design CDs to select a design CD that would produce an optimal contrast in the image transmitted by the chromeless phase mask during the photolithographic process;
determining the dose of the exposure light that will produce a minimum target ADI CD when a chromeless phase shift mask whose phase shifters have the optimum design CD is used in the photolithographic process;
determining another set of ADI CDs of features of a pattern which will be produced by the photolithographic process when the process uses a chromeless phase shift mask under conditions wherein the phase shifters of the chromeless phase shift mask each have the optimum design CD and produce several different phase differences in a range 150 to 180 degrees, and the process is carried out using the exposure light at the dose determined to produce the minimum target ADI CD;
correlating the another set of ADI CDs to the phase differences in the range of 150 to 180 degrees;
using the correlation between the set of ADI CDs and the phase differences to determine first and second phase differences, in the range of 150 to 180 degrees, which when produced in the exposure light during a photolithographic process, by a chromeless phase shift mask, will produce a pattern whose features have first and second desired ADI CDs, respectively;
etching a mask substrate to form first recesses each having a width equal to the optimal design CD and a depth that will produce the first phase difference in the exposure light transmitted by the chromeless phase shift mask substrate during the photolithographic process; and
further etching the mask substrate to extend one of the first recesses further into the mask to a depth that will produce the second phase difference in the exposure light transmitted by the chromeless phase shift mask substrate during the same photolithographic process.

17. The method of claim 16, wherein the correlating of the ADI CDs to the design CDs comprises plotting a curve of the ADI CDs with respect to design CDs, and the selecting of the design CD that would produce the optimal contrast comprises selecting from the curve the design CD by which the optimum focus can be obtained in the photolithographic process.

18. The method of claim 16, wherein the several different phase differences differ by increments of 5 degrees from 150 degrees to 180 degrees.

19. The method of claim 16, wherein the first desired ADI CD is 80 nm or less and the second desired ADI CD is greater than 80 nm.
